(19) United States
(12) Patent Application Publication
(10) Pub. No.: US 2023/0095839 A1
(43) Pub. Date: Mar. 30, 2023

(54) ARRAY SUBSTRATE, DISPLAY PANEL AND DRIVING METHOD THEREOF

(71) Applicants: Chengdu BOE Optoelectronics Technology Co., Ltd., Chengdu, Sichuan Province (CN); BOE Technology Group Co., Ltd., Beijing (CN)

(72) Inventors: Bin JI, Beijing (CN); Mite DENG, Beijing (CN); Tianma LI, Beijing (CN)

(21) Appl. No.: 16/979,608

(22) PCT Filed: Nov. 29, 2019
(86) PCT No.: PCT/CN2019/122191

§ 371 Date: Sep. 10, 2020

(51) Int. Cl. G09G 3/00; H01L 27/12

(52) U.S. Cl. CPC G09G 3/006; H01L 27/124; G09G 2380/10; G09G 2330/08; G09G 3/3648

(57) ABSTRACT

Disclosed are an array substrate, a display panel and a driving method thereof. As the control unit is provided between the first electrode and the test circuit, when the panel is subsequently tested, the control unit may provide the circuit control signal received by the first electrode to the test circuit under the control of the third electrode, so as to detect whether the panel is qualified by using the test circuit. During subsequent display, the control unit may be used to cut off the first electrode from the test circuit, and fundamentally cut off the connection between the first electrode, and the test circuit and a flexible printed circuit, so that a display abnormality does not occur even if the first electrode is short-circuited.

### CROSS REFERENCE TO RELATED APPLICATIONS

The present application is a national phase entry under 35 U.S.C. § 371 of International Application No. PCT/CN2019/122191, filed on Nov. 29, 2019. The entire disclosure of the above application is incorporated herein by reference.

### FIELD

The present disclosure relates to the field of display technology, in particular to an array substrate, a display panel and a driving method thereof.

### BACKGROUND

After cutting of display panel, as shown in FIG. 1, a test circuit 02 needs to be energized through test electrodes 01 in a bezel area to light up a screen so as to detect whether pixels work normally. After the panel passes the test, the display panel needs to be bonded to a flexible printed circuit (FPC) 03 to be assembled into a display module. During the display module works, to ensure that the display module can work normally, the FPC 03 provides a low-level signal to the test electrodes 01 to turn off the test circuit 02.

During the bonding, there is a probability that a conductive adhesive covering the test electrodes is short-circuited with a wire in the bezel area, causing abnormal voltages on the test electrodes during display, thereby resulting in abnormal display.

### SUMMARY

In view of this, embodiments of the present disclosure provide an array substrate, a display panel and a driving method thereof. Specific solutions are as follows.

An embodiment of the present disclosure provides an array substrate having a display area and a bezel area. The bezel area is provided with a test circuit, a first electrode for providing a circuit control signal to the test circuit, and a plurality of second electrodes for providing test signals to the test circuit. The bezel area is further provided with a control unit between the first electrode and the test circuit, and a third electrode for providing a switch control signal to the control unit. An input terminal of the control unit is connected to the first electrode, and an output terminal of the control unit is connected to the test circuit, and a control terminal of the control unit is connected to the third electrode. The control unit is configured to connect or disconnect the first electrode and the test circuit under the control of the third electrode.

In some embodiments of the present disclosure, the control unit is a switching transistor; and the switching transistor has a control pin connected to the third electrode, a first pin connected to the first electrode, and a second pin connected to the test circuit.

In some embodiments of the present disclosure, the third electrode and the first electrode are the same electrode.

In some embodiments of the present disclosure, the switching transistor may be an N-type transistor or a P-type transistor.

In some embodiments of the present disclosure, a transistor array is provided in the display area, and film layers with the same function, of the switching transistor and of transistors in the transistor array are provided in the same layer and made of the same material.

In some embodiments of the present disclosure, the first electrode, the plurality of second electrodes and the third electrode are arranged in parallel.

In some embodiments of the present disclosure, the first electrode, the plurality of second electrodes and the third electrode are provided in the same layer and made of the same material.

Correspondingly, an embodiment of the present disclosure further provides a display panel, including any of the above-mentioned array substrates provided by embodiments of the present disclosure.

In some embodiments of the present disclosure, the display panel further includes a drive circuit bonded to the bezel area of the display panel; and the drive circuit is connected to a node between the output terminal of the control unit and the test circuit through a trace on the array substrate.

Correspondingly, an embodiment of the present disclosure further provides a display module, including any of the above-mentioned display panels provided by embodiments of the present disclosure and a middle frame carrying the display panel. The display panel includes an array substrate and an opposite substrate. Where the first electrode, the second electrodes and the third electrode are located at an area that is not covered by the opposite substrate of the array substrate; and a conductive adhesive is further provided on a side of the opposite substrate facing away from the array substrate, and an orthographic projection of the conductive adhesive on the array substrate covers the area, that is not covered by the opposite substrate, of the array substrate.

Correspondingly, an embodiment of the present disclosure further provides a driving method of any of the above-mentioned display panel. During a panel test, the driving method includes:

providing the circuit control signal to the first electrode, providing the test signals to the plurality of second electrodes, and providing a switch-on signal to the third electrode;

providing the circuit control signal received by the first electrode to the test circuit, in response to that the control unit is turned on under the control of the third electrode, and; and

testing the display panel based on the test signals provided by the second electrodes to the test circuit.

In some embodiments, in the driving method provided by the embodiment of the present disclosure, in the case where the display panel includes the drive circuit, during display, the driving method includes:

disconnecting, by the control unit, the first electrode and the test circuit, under the control of the third electrode; and

controlling, by the drive circuit, the test circuit to be turned off, and controlling the display panel to display.

### BRIEF DESCRIPTION OF THE DRAWINGS

FIG. 1 is a schematic structural diagram of a display panel in the related art;

FIG. 2 is a partial view of a vehicle-mounted display module in some embodiments of the present disclosure;

FIG. 3 is a section view of the vehicle-mounted display module along a line B-B as indicated in FIG. 1;

FIG. 4 is a schematic structural diagram of an array substrate provided by an embodiment of the present disclosure;

FIG. 5 is a schematic structural diagram of another array substrate provided by an embodiment of the present disclosure;

FIG. 6 is a schematic structural diagram of still another array substrate provided by an embodiment of the present disclosure;

FIG. 7 is a schematic structural diagram of a display panel provided by an embodiment of the present disclosure;

FIG. 8 is a schematic structural diagram of another display panel provided by an embodiment of the present disclosure;

FIG. 9 is a schematic flow diagram of a driving method of a display panel provided by an embodiment of the present disclosure; and

FIG. 10 is a schematic flow diagram of another driving method of a display panel provided by an embodiment of the present disclosure.

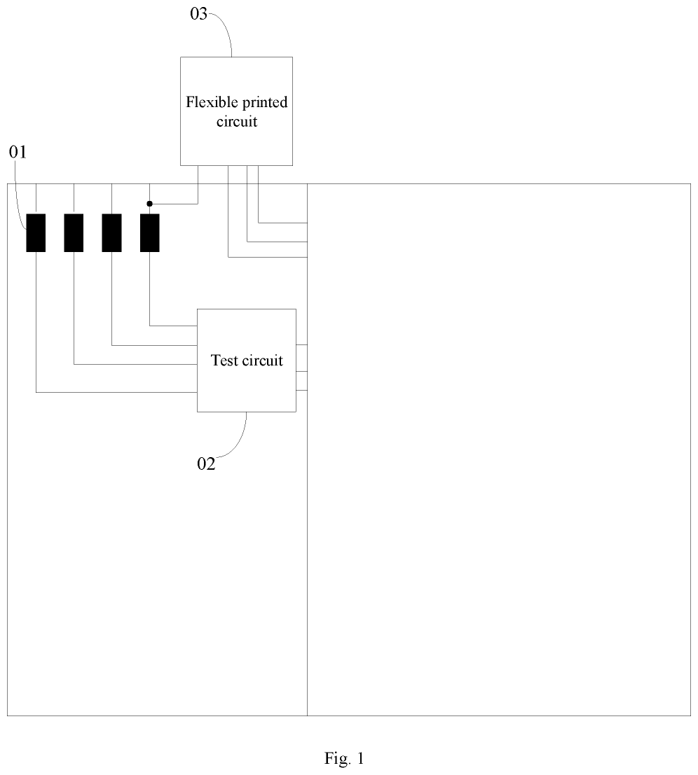

### DETAILED DESCRIPTION OF THE EMBODIMENTS

A small-sized liquid crystal display device, such as a vehicle-mounted liquid crystal display device, is usually provided with a display module.

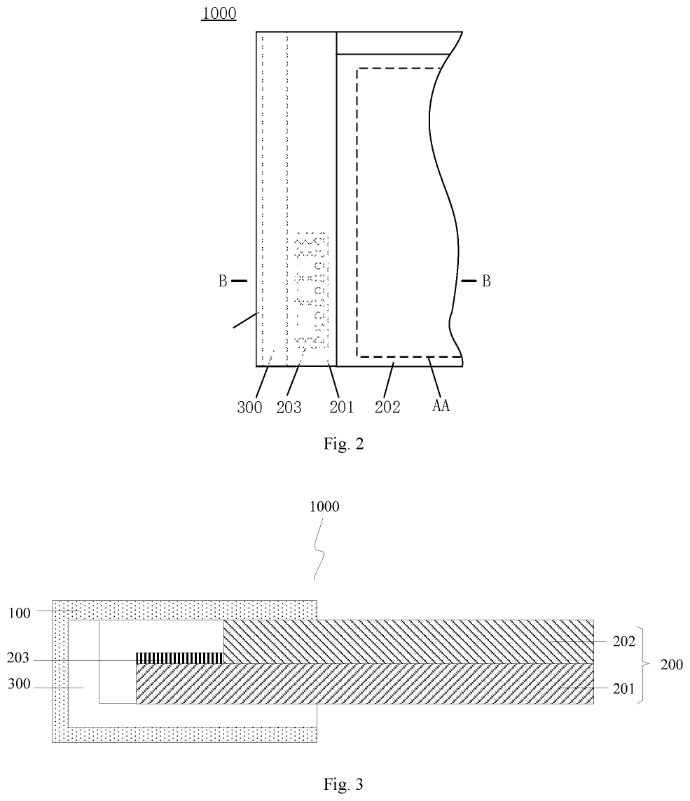

Some embodiments of the present disclosure provide a vehicle-mounted display module. Referring to FIGS. 2 and 3, the display module 1000 includes a display panel 200, a frame 300, and a cell tape 100, where the display panel 200 adheres to the frame 300 via the cell tape 100. The frame 300 is configured to accommodate a strip light, an optical film and the like, and to hold the display panel 200. The frame 300 generally includes a back plate and a bezel.

The above-mentioned display panel 200 generally has a display area AA and a non-display area at the periphery of the display area. The display panel 200 includes an array substrate 201 and a color filter substrate 202 disposed on the array substrate 201. In the case where the display panel 200 is a liquid crystal display panel, liquid crystals (not shown) are provided between the array substrate 201 and the color filter substrate 202. In addition, an edge portion of at least one side of the array substrate 201 and a corresponding edge portion of the color filter substrate 202 are not aligned. That is, the array substrate 201 has an area not covered by the color filter substrate 202. The area at least includes at least one of a detection electrode or signal line bonding area (such as a PAD area) to be configured to connect a screen detection device, a driver chip (IC), a screen driver board or the like. That is, a conductive portion 203 in the display panel 200 is usually located in this area, and the conductive portion 203 includes at least one type of conductive elements of signal line wires or line detection electrodes. In addition, the conductive portion 203 as a component of the array substrate 201 can be prepared together with a pixel drive circuit in the array substrate 201 during a preparing process of the array substrate 201.

During the actual use of the vehicle-mounted display module 1000, the frame 300 is prone to deformation by force due to various reasons such as the use environment and the action of external forces. For example, in a high-temperature environment or after the vehicle-mounted display module 1000 is mounted in a vehicle such as an automobile, vibration is liable to occur due to shaking or bumping of the vehicle during traveling. It has been found through research by the inventor that after the frame 300 is deformed by force, the display panel 200 is liable to be displaced relative to the frame 300 in a direction perpendicular to the display surface, so that the cell tape 100 comes into contact with the conductive portion 203 in the display panel 200. As the cell tape 100 that adheres the display panel 200 to the frame 300 is generally conductive, once the cell tape 100 comes into contact with the conductive portion 203 in the display panel 200, a part of circuitry in the display panel 200 will be short-circuited, thereby causing poor display of the display panel 200.

Based on this, embodiments of the present disclosure provide an array substrate, a display panel and a driving method thereof to solve the problem of abnormal display caused by short-circuiting of a test electrode in the prior art.

To make the above objectives, features and advantages of the present disclosure more obvious and understandable, the present disclosure will be further described below in conjunction with the accompanying drawings and embodiments. However, the exemplary embodiments may be implemented in various forms, and should not be construed as being limited to the embodiments set forth herein; on the contrary, these embodiments are provided to make the present disclosure more comprehensive and complete, and fully convey the concept of the exemplary embodiments to those skilled in the art. Same reference numerals in the drawings denote same or similar structures, and thus repeated description thereof will be omitted. All words expressing positions and directions in the present disclosure use the drawings as examples for illustration, but changes may be made as needed, and the changes are encompassed within the protection scope of the present disclosure. The drawings of the present disclosure are only used for illustrating relative positional relationships, and do not represent the true scales.

It should be noted that specific details are set forth in the following description to fully understand the present disclosure. However, the present disclosure can be implemented in many other ways different from those described herein, and those skilled in the art can make similar generalizations without departing from connotations of the present disclosure. Therefore, the present disclosure is not limited by the specific embodiments disclosed below. The subsequent description of the specification is preferred embodiments for implementing the present application, but the description is for the purpose of illustrating general principles of the present application and is not intended to limit the scope of the present application. The protection scope of the present application shall be defined by the appended claims.

An array substrate, a display panel and a driving method thereof provided by the embodiments of the present disclosure will be described in detail below in conjunction with the drawings.

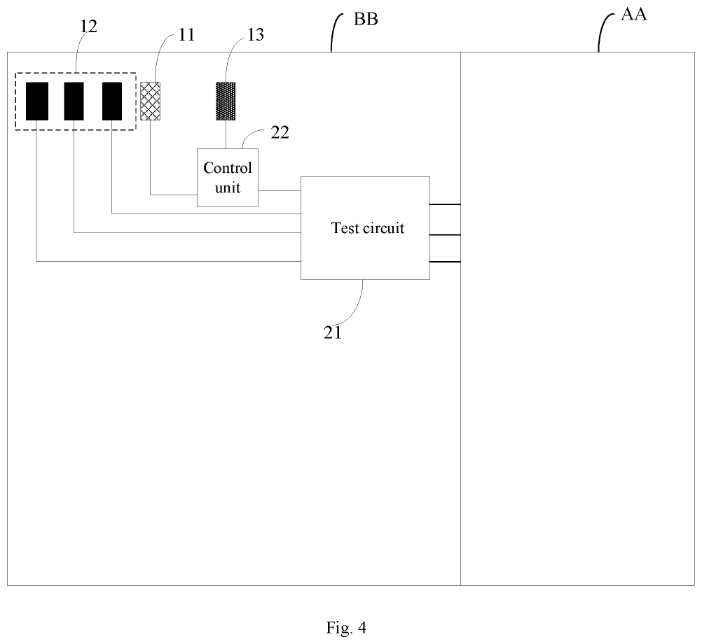

An array substrate provided by an embodiment of the present disclosure, as shown in FIG. 4, has a display area AA and a bezel area BB. The bezel area BB is provided with a test circuit 21, a first electrode 11 for providing a circuit control signal to the test circuit 21, and a plurality of second electrodes 12 for providing test signals to the test circuit 21;

the bezel area BB is further provided with a control unit 22 between the first electrode 11 and the test circuit 21 and a third electrode 13 for providing a switch control signal to the control unit 22;

an input terminal of the control unit 22 is connected to the first electrode 11, and an output terminal of the control unit 22 is connected to the test circuit 21, and a control terminal of the control unit 22 is connected to the third electrode 13; and

the control unit 22 is configured to connect or disconnect the first electrode and the test circuit 21 under the control of the third electrode 13.

In the array substrate provided by the embodiment of the present disclosure, as the control unit is provided between the first electrode and the test circuit, when a panel is subsequently tested, the control unit may provide the circuit control signal received by the first electrode to the test circuit under the control of the third electrode, so as to detect whether the panel is qualified by using the test circuit. During subsequent display, the control unit may be used to disconnect the first electrode and the test circuit, and thus disconnect the first electrode, and the test circuit and a flexible printed circuit, so that panel display is not influenced even if the first electrode is short-circuited.

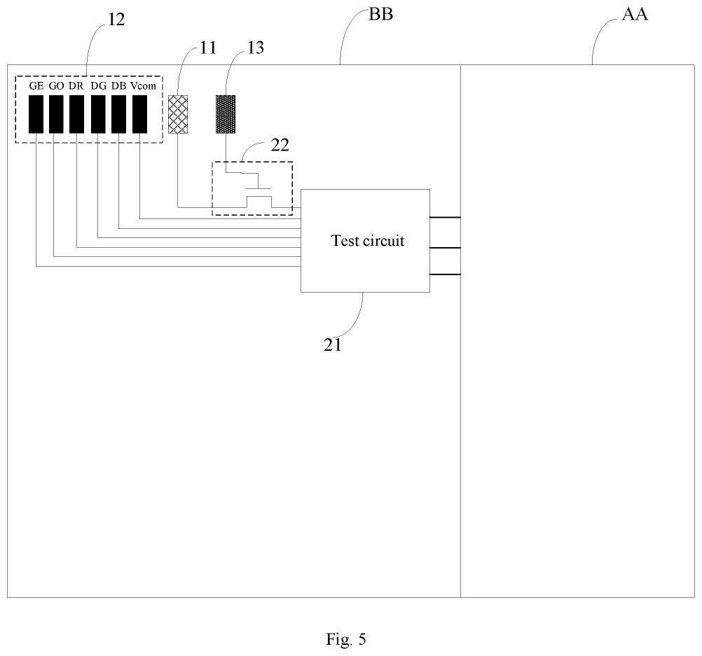

In some embodiments, as the display panel is bonded to the drive circuit after being tested to be qualified, a separate electrode (test pad) is needed to receive a signal for testing during the test. In some embodiments, as shown in FIG. 5, the second electrodes 12 generally include an electrode GE for receiving an odd-row gate line signal, an electrode GO for receiving an even-row gate line signal, an electrode DR for receiving a data signal of an R sub-pixel, an electrode DG for receiving a data signal of a G sub-pixel, an electrode DB for receiving a data signal of a B sub-pixel, and an electrode Vcom for receiving a common electrode signal. Of course, the number of second electrodes may be different in different display panels, and is specifically set according to actual conditions, which is not limited herein.

During testing of the display panel, a circuit control signal is provided to the first electrode 11, test signals are provided to the second electrodes 12, and a switch control signal is provided to the third electrode 13. When the third electrode 13 controls the control unit 22 to be turned on, the circuit control signal received by the first electrode 11 is provided to the test circuit 21, and after receiving the circuit control signal, the test circuit 21 provides the test signals received by the second electrodes 12 to signal lines of the display area of the display panel. Here the electrode GE provides the received odd-row gate line signal to odd-row sub-pixels to be tested, the electrode GO provides the received even-row gate line signal to even-row sub-pixels to be tested, and the electrode DR, the electrode DG and the electrode DB respectively provide a data voltage to sub-pixels to be tested, and the electrode Vcom provides a common voltage to the display panel, so as to light up sub-pixels of the display panel to achieve the purpose of detection.

It should be noted that, in the array substrate provided by the embodiment of the present disclosure, the test circuit includes any circuit structure for implementing the testing of the panel, and the specific structure is not limited herein.

Optionally, in the array substrate provided by the embodiment of the present disclosure, as shown in FIG. 5, the control unit 22 is a switching transistor having a control pin connected to the third electrode 13, a first pin connected to the first electrode 11, and a second pin connected to the test circuit 21. Thus, the existing panel technology can be used for preparation, so that the manufacture is convenient and simple, and the cost is low. Moreover, the switching transistor does not cause additional power consumption.

Further, in the array substrate provided by the embodiment of the present disclosure, the switching transistor may be an N-type transistor or a P-type transistor, which is not limited herein. In some embodiments, in the case where the switching transistor is an N-type transistor, the switching transistor can be turned on when the switch control signal received by the third electrode is a high level signal, and the switching transistor can be cut off when the switch control signal received by the third electrode is a low level signal; and in the case where the switching transistor is a P-type transistor, the switching transistor can be turned on when the switching control signal received by the third electrode is a low-level signal, and the switching transistor can be cut off when the switching control signal received by the third electrode is a high-level signal.

In some embodiments, in the array substrate provided by the embodiment of the present disclosure, a transistor array is provided in the display area. The transistor array generally includes a switching transistor, and also includes a driving transistor in some cases. The transistor array is used to control the sub-pixels in the display panel.

Optionally, in the array substrate provided by the embodiment of the present disclosure, film layers with the same function, of the switching transistor and of transistors in the transistor array are provided in the same layer and made of the same material. For example, a transistor generally includes a source, a drain, an active layer and a gate insulating layer. The drain of the switching transistor is arranged in the same layer as the drains of the transistors in the transistor array, the source of the switching transistor is arranged in the same layer as the sources of the transistors in the transistor array, the gate of the switching transistor is arranged in the same layer as the gates of the transistors in the transistor array, and the gate insulating layer of the switching transistor is arranged in the same layer as the gate insulating layers of the transistors in the transistor array. Thus, in spite of the addition of the control unit, the added control unit can be formed, by changing the pattern formed by patterning, at the time of forming the transistor array, without adding an extra patterning process, so the cost is lower.

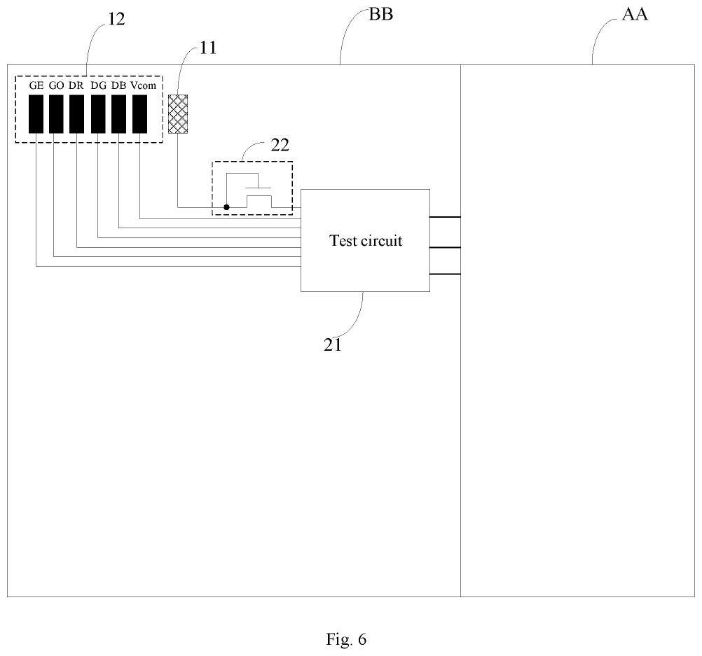

Further, in the array substrate provided by the embodiment of the present disclosure, as shown in FIG. 6, the third electrode 13 and the first electrode 11 are the same electrode. That is, both the gate and the source of the switching transistor are connected to the first electrode, and the switching transistor is connected to form a diode structure. Thus, the arrangement of the third electrode 13 may be omitted, but it is required that the circuit control signal received by the first electrode 11 is capable of turning on the switching transistor.

Optionally, in the array substrate provided by the embodiment of the present disclosure, the first electrode, the plurality of second electrodes and the third electrode are provided in the same layer and made of the same material, so there is no need to increase the patterning process, and the first electrode, the plurality of second electrodes and the third electrode can be formed at the same time by one patterning process.

Further, in the array substrate provided by the embodiment of the present disclosure, the first electrode, the plurality of second electrodes and the third electrode may be provided in the same layer as the gate, source or drain of the switching transistor.

Optionally, in the array substrate provided by the embodiment of the present disclosure, as shown in FIGS. 4 to 6, the first electrode 11, the plurality of second electrodes 12 and the third electrode 13 are arranged in parallel, to facilitate wiring layout.

Based on the same inventive concept, an embodiment of the present disclosure further provides a display panel, including any of the above-mentioned array substrates provided by embodiments of the present disclosure. As the problem-solving principle of the display panel is similar to that of the above-mentioned array substrate, for the implementation of the display panel, reference may be made to the implementation of the above-mentioned array substrate, and repeated description is omitted.

In some embodiments, the display panel generally further includes an opposite substrate arranged opposite to the array substrate. The display panel may be a liquid crystal display panel or an OLED panel, which is not limited herein.

In some embodiments, in the case where the display panel is a liquid crystal display panel, a liquid crystal layer is further provided between the array substrate and the opposite substrate.

In the display panel provided by the embodiment of the present disclosure, as the control unit between the first electrode and the test circuit is added to the array substrate, during the panel test, the control unit may provide the circuit control signal received by the first electrode to the test circuit under the control of the third electrode, so as to detect whether the panel is qualified by using the test circuit. During subsequent display, the control unit may be used to disconnect the first electrode and the test circuit, and thus disconnect the connection between the first electrode and the test circuit and a flexible circuit board, so that display is not influenced even if the first electrode is short-circuited.

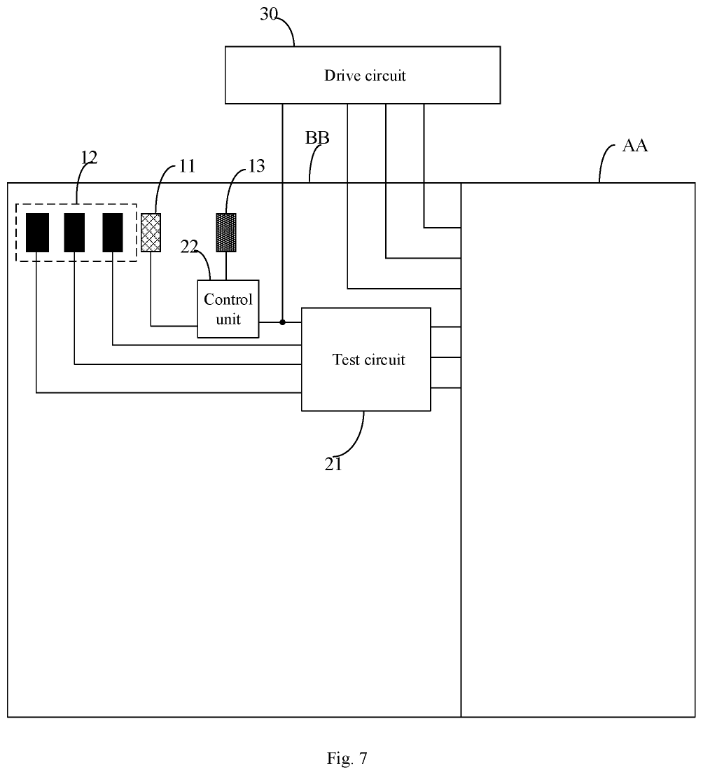

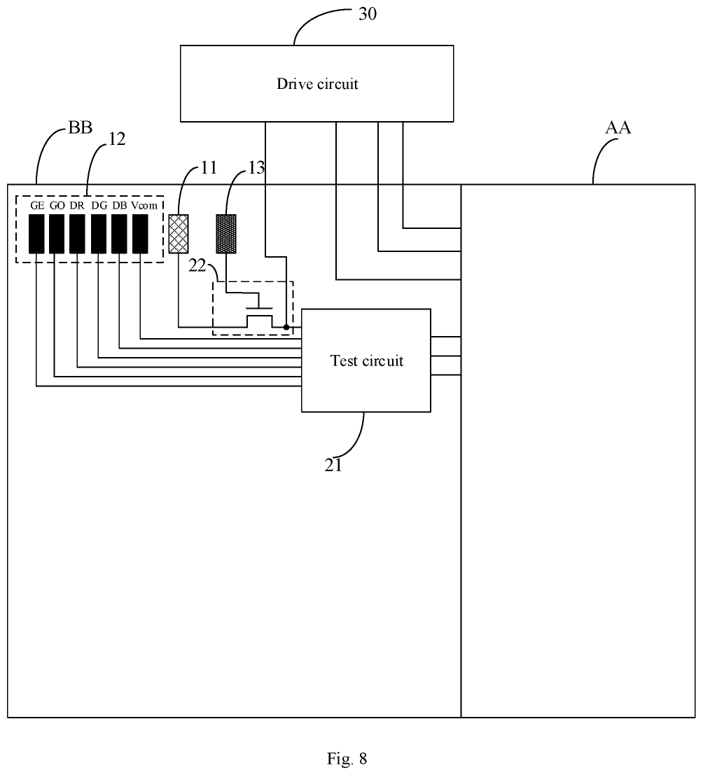

Further, the display panel provided by the embodiment of the present disclosure, as shown in FIGS. 7 and 8, further includes a drive circuit 30 bonded to the bezel area BB of the display panel; and

the drive circuit 30 is connected to a node between the output terminal of the control unit 22 and the test circuit 21 through a wire on the array substrate.

In some embodiments, the drive circuit may be a flexible printed circuit or the like, which is not limited herein.

In some embodiments, during display, the drive circuit controls the test circuit to be in an off state, and controls the display panel to perform display. For example, the test circuit starts working in response to a high-level signal, and is turned off in response to a low-level signal. Thus, during display, the drive circuit provides a low-level signal to the test circuit so that the test circuit is turned off.

In some embodiments, the drive circuit generally includes a timing controller, a data driving circuit, a gate driving circuit and the like, which are respectively configured to transmit to the display panel a timing signal, a gate control signal, a data signal and the like that can be recognized by the display panel, which will not be described in detail herein.

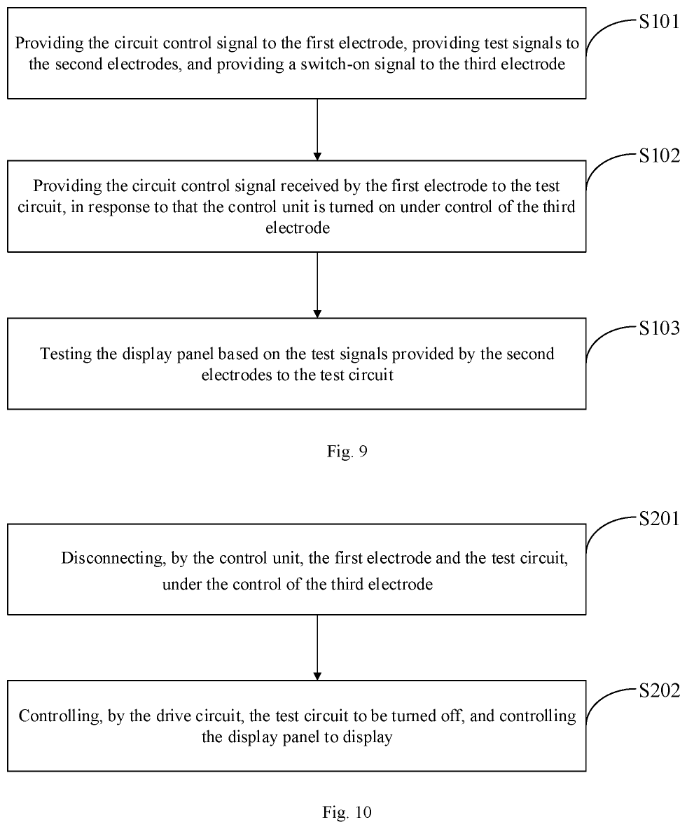

Based on the same inventive concept, an embodiment of the present disclosure further provides a driving method of the above-mentioned display panel. During a panel test, as shown in FIG. 9, the driving method includes:

S101. providing the circuit control signal to the first electrode, providing the test signals to the second electrodes, and providing a switch-on signal to the third electrode;

S102. providing the circuit control signal received by the first electrode to the test circuit, in response to that the control unit is turned on under the control of the third electrode; and

S103. testing the display panel based on the test signals provided by the second electrodes to the test circuit.

In the above-mentioned driving method provided by the embodiment of the present disclosure, during the panel test, the control unit is controlled to bring the first electrode and the test circuit into conduction, thereby achieving a panel test function.

Further, in the driving method provided by the embodiment of the present disclosure, in the case where the display panel includes the drive circuit, during display, as shown in FIG. 10, the driving method includes:

S201. disconnecting the first electrode and the test circuit, by the control unit, under the control of the third electrode; and

S202. controlling, by the drive circuit, the test circuit to be turned off, and controlling the display panel to display.

In the above-mentioned driving method provided by the embodiment of the present disclosure, during display, the control unit is controlled to disconnect the first electrode and the test circuit, and the drive circuit directly controls the test circuit to be turned off, but not through the first electrode, thereby disconnecting the first electrode and the test circuit, and thus disconnecting the first electrode, and the test circuit and the drive circuit, so that display is not influenced even if the first electrode is short-circuited.

Based on the same inventive concept, an embodiment of the present disclosure further provides a display module, including any of the above-mentioned display panels provided by embodiments of the present disclosure and a bezel holding the display panel;

the display panel includes an array substrate and an opposite substrate; the first electrode, the second electrodes and the third electrode are located at an area that is not covered by the opposite substrate of the array substrate;

a conductive adhesive is further provided on a side of the opposite substrate facing away from the array substrate, and an orthographic projection of the conductive adhesive on the array substrate covers the area that is not covered by the opposite substrate of the array substrate.

In some embodiments, for the display module provided by the embodiment of the present disclosure, reference may be made to the display module shown in FIG. 3, wherein the bezel is a part of the frame 300, and the conductive adhesive is at least provided in a side of a cell tape 100 facing to a side of the array substrate 201 facing to the opposite substrate 202. The conductive area 203 includes the first electrode, the second electrodes, the third electrode and the control unit in the present disclosure.

In the display module provided by the embodiment of the present disclosure, as the control unit between the first electrode and the test circuit is added to the array substrate, during the panel test, the control unit may provide the circuit control signal received by the first electrode to the test circuit under the control of the third electrode, so as to detect whether the panel is qualified by using the test circuit. During display, the control unit may be used to disconnect the first electrode and the test circuit, and thus disconnect the first electrode, and the test circuit and a flexible printed circuit, so that display is not influenced even if the conductive adhesive causes the first electrode to be short-circuited.

In some embodiments, the display module may be a mobile phone, a tablet computer, a television, a display, a notebook computer, a digital photo frame, a navigator, or any other product or component with a display function. For the implementation of the display module, reference may be made to the embodiment of the above-mentioned display panel, and repeated description is omitted.

In the above-mentioned array substrate, display panel and driving method thereof provided by the embodiments of the present disclosure, as the control unit between the first electrode and the test circuit is added to the array substrate, during the panel test, the control unit may provide the circuit control signal received by the first electrode to the test circuit under the control of the third electrode, so as to detect whether the panel is qualified by using the test circuit. During subsequent display, the control unit may be used to disconnect the first electrode and the test circuit, and thus disconnect the first electrode, and the test circuit and a flexible printed circuit, so that display is not influenced even if the first electrode is short-circuited.

Evidently, those skilled in the art can make various modifications and variations to the present disclosure without departing from the spirit and scope of the present disclosure. Thus, the present disclosure is also intended to encompass these modifications and variations thereto so long as the modifications and variations come into the scope of the claims appended to the present disclosure and their equivalents.

1. An array substrate, having a display area and a bezel area, and comprising in the bezel area:
a test circuit;
a first electrode for providing a circuit control signal to the test circuit;
a plurality of second electrodes for providing test signals to the test circuit;
a control unit between the first electrode and the test circuit; and
a third electrode for providing a switch control signal to the control unit;
wherein
an input terminal of the control unit is connected to the first electrode, an output terminal of the control unit is connected to the test circuit, and a control terminal of the control unit is connected to the third electrode; and
the control unit is configured to connect or disconnect the first electrode and the test circuit under a control of the third electrode.

2. The array substrate according to claim 1, wherein the control unit is a switching transistor; and
a control end of the switching transistor is connected to the third electrode, a first end of the switching transistor is connected to the first electrode, and a second end of the switching transistor is connected to the test circuit.

3. The array substrate according to claim 2, wherein the third electrode and the first electrode are a same electrode.

4. The array substrate according to claim 2, wherein the switching transistor is an N-type transistor or a P-type transistor.

5. The array substrate according to claim 2, comprising in the display area a transistor array, wherein
film layers, with a same function, of the switching transistor and of transistors in the transistor array are arranged in a same layer and made of a same material.

6. The array substrate according to claim 1, wherein the first electrode, the plurality of second electrodes and the third electrode are arranged in parallel.

7. The array substrate according to claim 1, wherein the first electrode, the plurality of second electrodes and the third electrode are provided in a same layer and made of a same material.

8. A display panel, comprising an array substrate, wherein the array substrate has a display area and a bezel area, and comprises in the bezel area:
a test circuit;
a first electrode for providing a circuit control signal to the test circuit;
a plurality of second electrodes for providing test signals to the test circuit;
a control unit between the first electrode and the test circuit; and
a third electrode for providing a switch control signal to the control unit;
wherein
an input terminal of the control unit is connected to the first electrode, an output terminal of the control unit is connected to the test circuit, and a control terminal of the control unit is connected to the third electrode; and
the control unit is configured to connect or disconnect the first electrode and the test circuit under a control of the third electrode.

9. The display panel according to claim 8, further comprising a drive circuit bonded to the bezel area of the display panel; and
the drive circuit is connected to a node between the output terminal of the control unit and the test circuit via a wire on the array substrate.

10. A display module, comprising the display panel of claim 8 and a bezel holding the display panel;
the display panel comprises:
an array substrate and an opposite substrate;
wherein the first electrode, the second electrodes and the third electrode are located in an area, not covered by the opposite substrate, of the array substrate; and
a conductive adhesive is provided on a side of the opposite substrate facing away from the array substrate, and an orthographic projection of the conductive adhesive on the array substrate covers the area not covered by the opposite substrate of the array substrate.

11. A method of driving the display panel of claim 8, for testing the display panel, comprising:
providing the circuit control signal to the first electrode, providing the test signals to the plurality of second electrodes, and providing a switch-on signal to the third electrode;
providing the circuit control signal received by the first electrode to the test circuit, in response to that the control unit is turned on under the control of the third electrode; and
testing the display panel based on the test signals provided by the second electrodes to the test circuit.

12. (canceled)

13. The array panel according to claim 8, wherein the control unit is a switching transistor; and
a control end of the switching transistor is connected to the third electrode, a first end of the switching transistor is connected to the first electrode, and a second end of the switching transistor is connected to the test circuit.

14. The array panel according to claim 13, wherein the third electrode and the first electrode are a same electrode.

15. The array panel according to claim 13, wherein the switching transistor is an N-type transistor or a P-type transistor.

16. The array panel according to claim 13, comprising in the display area a transistor array, wherein
film layers, with a same function, of the switching transistor and of transistors in the transistor array are arranged in a same layer and made of a same material.

17. The array substrate according to claim 8, wherein the first electrode, the plurality of second electrodes and the third electrode are arranged in parallel.

18. The array substrate according to claim 8, wherein the first electrode, the plurality of second electrodes and the third electrode are provided in a same layer and made of a same material.

19. A method of driving the display panel of claim 9, for testing the display panel, comprising:
providing the circuit control signal to the first electrode, providing the test signals to the plurality of second electrodes, and providing a switch-on signal to the third electrode;
providing the circuit control signal received by the first electrode to the test circuit, in response to that the control unit is turned on under the control of the third electrode; and
testing the display panel based on the test signals provided by the second electrodes to the test circuit.

20. A method of driving the display panel of claim 9, during display, comprising:
disconnecting, by the control unit, the first electrode and the test circuit, under the control of the third electrode; and
controlling, by the drive circuit, the test circuit to be turned off, and controlling the display panel to display.
